(19) United States
(12) Patent Application Publication
(10) Pub. No.: US 2026/0190236 A1
(43) Pub. Date: Jul. 2, 2026

(54) PACKAGE STRUCTURE

(71) Applicant: Advanced Semiconductor Engineering, Inc., Kaohsiung (TW)

(72) Inventors: Chung Ju YU, Kaohsiung (TW); Tsung-Wei LU, Kaohsiung (TW)

(73) Assignee: Advanced Semiconductor Engineering, Inc., Kaohsiung (TW)

(21) Appl. No.: 19/004,129

(22) Filed: Dec. 27, 2024

(51) Int. Cl. H05K 1/18; H05K 1/11

(52) U.S. Cl. CPC H05K 1/181; H05K 1/111; H05K 2201/09909; H05K 2201/10015; H05K 2201/1031; H05K 2201/10522

(57) ABSTRACT

A package structure is provided. The package structure includes a substrate, an electronic component, and a protective element. The substrate includes a first pad and a second pad. The electronic component is connected to the first pad and the second pad. The protective element is at least partially situated between the substrate and the electronic component. The protective element extends over the first pad by a first length and over the second pad by a second length different from the first length.

### BACKGROUND

### 1. Technical Field

The present disclosure relates generally to a package structure.

### 2. Description of the Related Art

Currently, components may be bonded to a device or a substrate by surface mount technology (SMT). However, solder materials on separate terminals of the component may flow and extend towards to each other during the reflow process, which may result in short circuits between the terminals.

### SUMMARY

In one or more arrangements, a package structure includes a substrate, an electronic component, and a protective element. The substrate includes a first pad and a second pad. The electronic component is connected to the first pad and the second pad. The protective element is at least partially situated between the substrate and the electronic component. The protective element extends over the first pad by a first length and over the second pad by a second length different from the first length.

In one or more arrangements, a package structure includes a substrate, an electronic component, and a first solder element. The substrate includes a first pad. The electronic component is disposed over the first pad and includes a first terminal. The first solder element connects the first terminal to the first pad. The first solder element includes a first lower portion between the first terminal and the first pad and having a first thickness. The first solder element further includes a lateral portion over a sidewall of the first terminal and having a second thickness less than the first thickness.

In one or more arrangements, a package structure includes a substrate, a first electronic component, and a first solder structure. The substrate includes a first pad exposed from an upper surface of the substrate. The first electronic component includes a first electrode and a first solder element covering the first electrode. The first solder structure connects the first solder element to the first pad. A contact surface between the first solder element and the first solder structure includes an irregular surface.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 1A is a cross-section of a portion of a package structure in accordance with some arrangements of the present disclosure.

FIG. 1B is a cross-section of a portion of a package structure in accordance with some arrangements of the present disclosure.

FIG. 1C is a cross-section of a portion of a package structure in accordance with some arrangements of the present disclosure.

FIG. 2A is a top view of a portion of a package structure in accordance with some arrangements of the present disclosure.

FIG. 2B is a top view of a portion of a package structure in accordance with some arrangements of the present disclosure.

FIG. 3 is a cross-section of a package structure in accordance with some arrangements of the present disclosure.

FIG. 4A to FIG. 4I illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

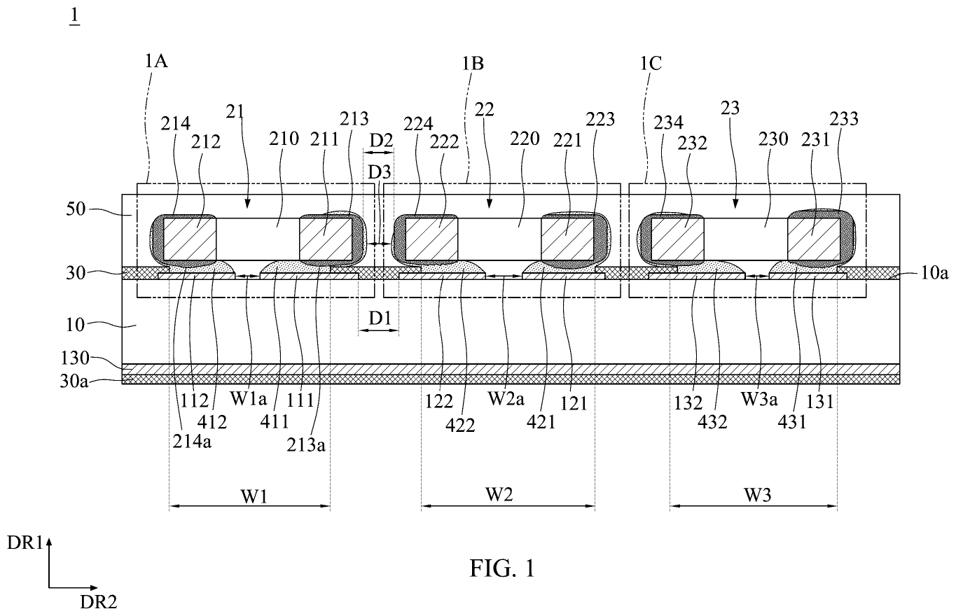

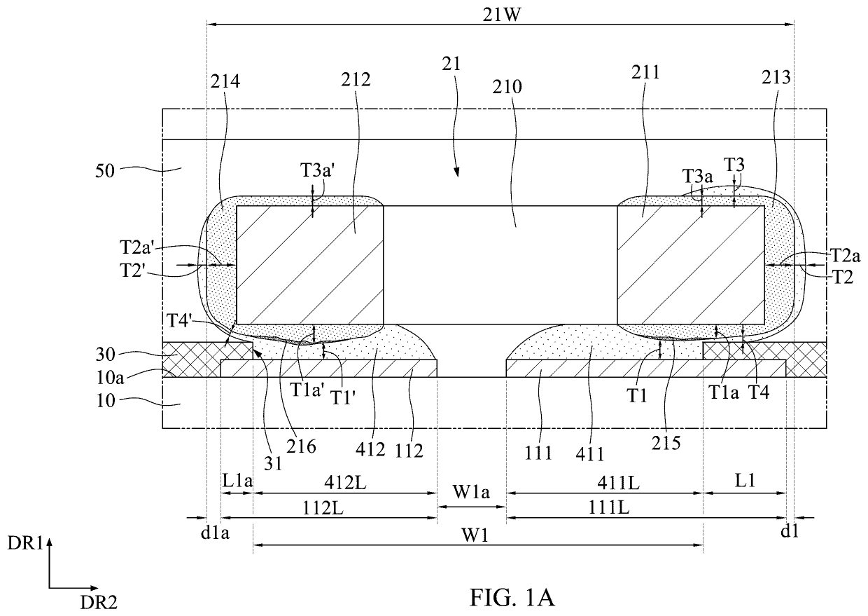

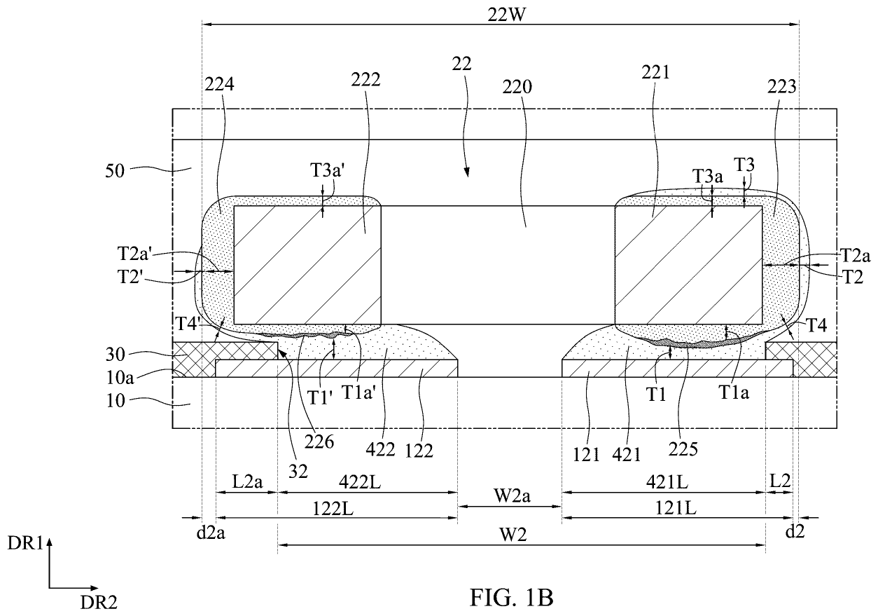

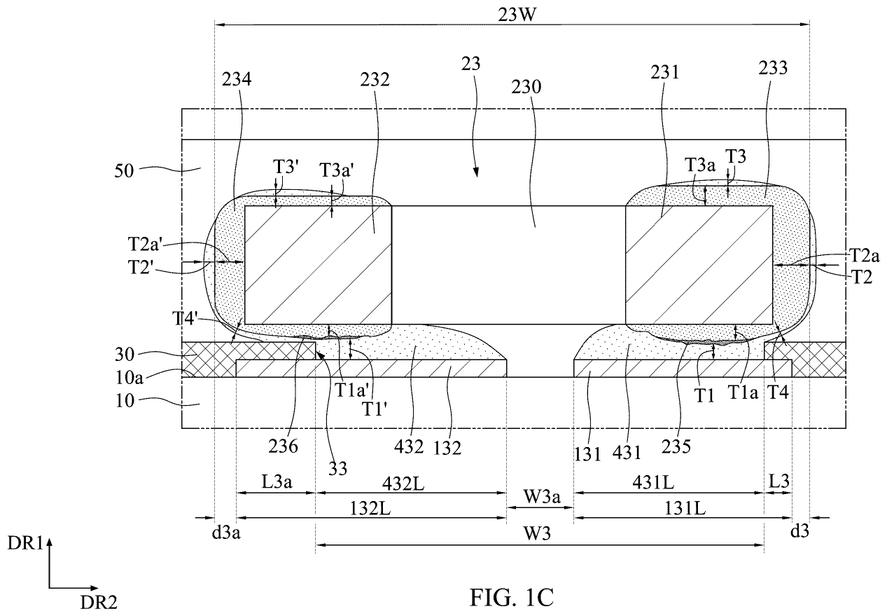

FIG. 1A is a cross-section of a package structure 1 in accordance with some arrangements of the present disclosure. FIG. 1A is a cross-section of a portion of a package structure 1 in accordance with some arrangements of the present disclosure. FIG. 1B is a cross-section of a portion of a package structure 1 in accordance with some arrangements of the present disclosure. FIG. 1C is a cross-section of a portion of a package structure 1 in accordance with some arrangements of the present disclosure. In some arrangements, FIG. 1A is a cross-section of a portion 1A of the package structure 1 illustrated in FIG. 1, FIG. 1B is a cross-section of a portion 1B of the package structure 1 illustrated in FIG. 1, and FIG. 1C is a cross-section of a portion 1C of the package structure 1 illustrated in FIG. 1. The package structure 1 may include a substrate 10, electronic components 21, 22, and 23, a protective element 30, a protective layer 30a, solder elements 411, 412, 421, 422, 431, and 432, and an encapsulant 50.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may include a surface 10a (also referred to as a top surface or an upper surface). In some arrangements, the substrate 10 includes pads 111, 112, 121, 122, 131, and 132 exposed from the surface 10a. The pads 111, 112, 121, 122, 131, and 132 may be electrically conductive pads. In some arrangements, the substrate 10 further includes a conductive layer 130 on a lower surface or a bottom surface of the substrate 10.

The electronic components 21, 22, and 23 may be connected to the substrate 10. The electronic components 21, 22, and 23 may be disposed over and electrically connected to the substrate 10. The electronic components 21, 22, and 23 may be or include passive components. In some arrangements, the electronic components 21, 22, and 23 include surface mount devices (SMDs). In some arrangements, the electronic components 21, 22, and 23 include capacitors or the like. In some arrangements, a distance D1 between the adjacent pads (e.g., the pads 111 and 112) of the substrate 10 is greater than a distance D2 between the adjacent electronic components (e.g., the electronic components 21 and 22).

In some arrangements, the electronic component 21 is connected to the pads 111 and 112. In some arrangements, the electronic component 21 is disposed over and electrically connected to the pads 111 and 112. In some arrangements, the pads 111 and 112 are spaced apart from each other by a distance W1a. In some arrangements, the electronic component 21 has a width 21W greater than a sum of a length 111L of the pad 111, a length 112L of the pad 112, and the distance W1a. In some arrangements, the pad 111 is recessed with respect to a side (or a first side) of the electronic component 21, and the pad 112 is recessed with respect to an opposite side (or a second side opposite to the first side) of the electronic component 21. In some arrangements, the pad 111 is recessed with respect to a side (or the first side) of the electronic component 21 by a distance d1, and the pad 112 is recessed with respect to an opposite side (or the second side) of the electronic component 21 by a distance d1a different from the distance d1.

In some arrangements, the electronic component 21 includes a base layer 210 and electrodes 211 and 212 (also referred to as “contacts”). The electrode 211 may be opposite to the electrode 212. The base layer 210 may be an insulating layer, e.g., a ceramic layer. In some arrangements, the electronic component 21 further includes a solder element 213 covering the electrode 211 and a solder element 214 covering the electrode 212. The electrode 211 and the solder element 213 may be referred to as a terminal (also referred to as “a first terminal”) of the electronic component 21, and the electrode 212 and the solder element 214 (also referred to as “a second terminal”) may be referred to as a terminal of the electronic component 21. In some arrangements, the terminals of the electronic component 21 are electrically connected to the pads 111 and 112, respectively. In some arrangements, at least one of the terminals may have a curved surface (e.g., a surface 213a) that is convex toward the pad 111 and/or the pad 112. In some arrangements, the solder element 213 of the terminal of the electronic component 21 has a curved surface 213a convex toward the pad 111. In some arrangements, the solder element 214 of the terminal of the electronic component 21 has a curved surface 214a convex toward the pad 112. In some arrangements, at least one of the terminals partially extends into the opening 31 of the protective element 30. In some arrangements, the solder element 214 of the terminal of the electronic component 21 extends into the opening 31 of the protective element 30. In some arrangements, the solder element 214 partially overlaps the protective element 30 is a direction DR2 substantially parallel to the surface 10a of the substrate 10.

Referring to FIG. 1A, in some arrangements, the solder element 213 includes a lower portion having a thickness T1a, a lateral portion having a thickness T2a, and an upper portion having a thickness T3a. In some arrangements, the solder element 214 includes a lower portion having a thickness T1a′, a lateral portion having a thickness T2a′, and an upper portion having a thickness T3a′. In some arrangements, the thickness T1a is different from the thickness T1a′. In some arrangements, the thickness T2a is different from the thickness T2a′. In some arrangements, the thickness T3a is different from the thickness T3a′.

In some arrangements, the electronic component 22 is connected to the pads 121 and 122. In some arrangements, the electronic component 22 is disposed over and electrically connected to the pads 121 and 122. In some arrangements, the pads 121 and 122 are spaced apart from each other by a distance W2a. In some arrangements, the electronic component 22 has a width 22W greater than a sum of a length 121L of the pad 121, a length 122L of the pad 122, and the distance W2a. In some arrangements, the pad 121 is recessed with respect to a side (or a first side) of the electronic component 22, and the pad 122 is recessed with respect to an opposite side (or a second side opposite to the first side) of the electronic component 22. In some arrangements, the pad 121 is recessed with respect to a side (or the first side) of the electronic component 22 by a distance d2, and the pad 122 is recessed with respect to an opposite side (or the second side) of the electronic component 22 by a distance d2a different from the distance d2.

In some arrangements, the electronic component 22 includes a base layer 220 and electrodes 221 and 222 (also referred to as “contacts”). The electrode 221 may be opposite to the electrode 222. The base layer 220 may be an insulating layer, e.g., a ceramic layer. In some arrangements, the electronic component 22 further includes a solder element 223 covering the electrode 221 and a solder element 224 covering the electrode 222. The electrode 221 and the solder element 223 may be referred to as a terminal (also referred to as “a first terminal”) of the electronic component 22, and the electrode 222 and the solder element 224 (also referred to as “a second terminal”) may be referred to as a terminal of the electronic component 22. In some arrangements, the terminals of the electronic component 22 are electrically connected to the pads 121 and 122, respectively. In some arrangements, at least one of the terminals may have a curved surface that is convex toward the pad 121 and/or the pad 122. In some arrangements, the solder element 223 of the terminal of the electronic component 22 has a curved surface convex toward the pad 121. In some arrangements, the solder element 224 of the terminal of the electronic component 22 has a curved surface convex toward the pad 122. In some arrangements, at least one of the terminals partially extends into the opening 32 of the protective element 30. In some arrangements, the solder element 224 of the terminal of the electronic component 22 extends into the opening 32 of the protective element 30. In some arrangements, the solder element 223 partially overlaps the protective element 30 is the direction DR2.

Referring to FIG. 1B, in some arrangements, the solder element 223 includes a lower portion having a thickness T1a, a lateral portion having a thickness T2a, and an upper portion having a thickness T3a. In some arrangements, the solder element 224 includes a lower portion having a thickness T1a′, a lateral portion having a thickness T2a′, and an upper portion having a thickness T3a′. In some arrangements, the thickness T1a is different from the thickness T1a′. In some arrangements, the thickness T2a is different from the thickness T2a′. In some arrangements, the thickness T3a is different from the thickness T3a′.

In some arrangements, the electronic component 23 is connected to the pads 131 and 132. In some arrangements, the electronic component 23 is disposed over and electrically connected to the pads 131 and 132. In some arrangements, the pads 131 and 132 are spaced apart from each other by a distance W3a. In some arrangements, the electronic component 23 has a width 23W greater than a sum of a length 131L of the pad 131, a length 132L of the pad 132, and the distance W3a. In some arrangements, the pad 131 is recessed with respect to a side (or a first side) of the electronic component 23, and the pad 132 is recessed with respect to an opposite side (or a second side opposite to the first side) of the electronic component 23. In some arrangements, the pad 131 is recessed with respect to a side (or the first side) of the electronic component 23 by a distance d3, and the pad 132 is recessed with respect to an opposite side (or the second side) of the electronic component 23 by a distance d3a different from the distance d3.

In some arrangements, the electronic component 23 includes a base layer 230 and electrodes 231 and 232 (also referred to as “contacts”). The electrode 231 may be opposite to the electrode 232. The base layer 230 may be an insulating layer, e.g., a ceramic layer. In some arrangements, the electronic component 23 further includes a solder element 233 covering the electrode 231 and a solder element 234 covering the electrode 232. The electrode 231 and the solder element 233 may be referred to as a terminal (also referred to as “a first terminal”) of the electronic component 23, and the electrode 232 and the solder element 234 (also referred to as “a second terminal”) may be referred to as a terminal of the electronic component 23. In some arrangements, the terminals of the electronic component 23 are electrically connected to the pads 131 and 132, respectively. In some arrangements, at least one of the terminals may have a curved surface that is convex toward the pad 131 and/or the pad 132. In some arrangements, the solder element 233 of the terminal of the electronic component 23 has a curved surface convex toward the pad 131. In some arrangements, the solder element 234 of the terminal of the electronic component 23 has a curved surface convex toward the pad 132. In some arrangements, at least one of the terminals partially extends into the opening 33 of the protective element 30. In some arrangements, the solder element 233 of the terminal of the electronic component 23 extends into the opening 33 of the protective element 30. In some arrangements, the solder element 233 partially overlaps the protective element 30 is the direction DR2.

Referring to FIG. 1C, in some arrangements, the solder element 233 includes a lower portion having a thickness T1a, a lateral portion having a thickness T2a, and an upper portion having a thickness T3a. In some arrangements, the solder element 234 includes a lower portion having a thickness T1a′, a lateral portion having a thickness T2a′, and an upper portion having a thickness T3a′. In some arrangements, the thickness T1a is different from the thickness T1a′. In some arrangements, the thickness T2a is different from the thickness T2a′. In some arrangements, the thickness T3a is different from the thickness T3a′.

The protective element 30 may be at least partially between the substrate 10 and the electronic components 21, 22, and 23. In some arrangements, the protective element 30 and the protective layer 30a are on opposite sides of the substrate 10. In some arrangements, the protective element 30 and the protective layer 30a may independently include an organic material, a solder mask, PI, ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

Referring to FIG. 1A, in some arrangements, the protective element 30 defines an opening 31 to partially expose the pads 111 and 112. In some arrangements, a width W1 of the opening 31 is less than a width 21W of the electronic component 21. In some arrangements, the protective element 30 extends over the pad 111 by a length L1 and over the pad 112 by a length L1a different from the length L1. In some arrangements, a length 111L of the pad 111 is different from a length 112L of the pad 112. In some arrangements, a length 111L of the pad 111 is greater than the length 112L of the pad 112, and the length L1 of the protective element 30 is greater than the length L1a of the protective element 30.

Referring to FIG. 1B, in some arrangements, the protective element 30 defines an opening 32 to partially exposed the pads 121 and 122. In some arrangements, a width W2 of the opening 32 is less than a width 22W of the electronic component 22. In some arrangements, the protective element 30 extends over the pad 121 by a length L2 and over the pad 122 by a length L2a different from the length L2. In some arrangements, a length 121L of the pad 121 is different from a length 122L of the pad 122. In some arrangements, a length 122L of the pad 122 is greater than the length 121L of the pad 121, and the length L2a of the protective element 30 is greater than the length L2 of the protective element 30.

Referring to FIG. 1C, in some arrangements, the protective element 30 defines an opening 33 to partially expose the pads 131 and 132. In some arrangements, a width W3 of the opening 33 is less than a width 23W of the electronic component 23. In some arrangements, the protective element 30 extends over the pad 131 by a length L3 and over the pad 132 by a length L3a different from the length L3. In some arrangements, a length 131L of the pad 131 is different from a length 132L of the pad 132. In some arrangements, a length 132L of the pad 132 is greater than the length 131L of the pad 131, and the length L3a of the protective element 30 is greater than the length L3 of the protective element 30.

The solder elements 411, 412, 421, 422, 431, and 432 may be disposed between the substrate 10 and the electronic components 21, 22, and 23. The solder elements 213, 214, 223, 224, 233, 234, 411, 412, 421, 422, 431, and 432 may be referred to as solder structures, solder layers, solder balls, reflowable elements, or the like. The solder elements may independently include Sn, Ag, Cu, SnSb, or an alloy thereof. In some arrangements, the solder elements 411, 412, 421, 422, 431, and 432 and the solder elements 213, 214, 223, 224, 233, and 234 include different materials.

Referring to FIG. 1A, in some arrangements, the solder element 411 contacts the pad 111 by a contact length 411L, the solder element 412 contacts the pad 112 by a contact length 412L, and the contact length 411L is substantially the same as the contact length 412L. In some arrangements, the solder element 411 connects the terminal (e.g., the electrode 211 and the solder element 213) of the electronic component 21 to the pad 111, and the solder element 412 connects the terminal (e.g., the electrode 212 and the solder element 214) of the electronic component 21 to the pad 112. In some arrangements, the solder element 411 electrically connects the terminal (e.g., the electrode 211 and the solder element 213) of the electronic component 21 to the pad 111, and the solder element 412 electrically connects the terminal (e.g., the electrode 212 and the solder element 214) of the electronic component 21 to the pad 112. In some arrangements, the solder element 411 connects or electrically connects the solder element 213 to the pad 111, and a bonding surface or a contact surface (e.g., the surface 213a) between the solder elements 411 and 213 includes an irregular surface. In some arrangements, the solder element 412 connects or electrically connects the solder element 213 to the pad 112, and a bonding surface or a contact surface (e.g., the surface 214a) between the solder elements 412 and 214 includes an irregular surface.

Referring to FIG. 1A, in some arrangements, the solder element 411 includes a first lower portion having a thickness T1 and between the terminal (e.g., the electrode 211 and the solder element 213) and the pad 111. In some arrangements, the solder element 411 further includes a lateral portion having a thickness T2 and over a sidewall of the terminal (e.g., the electrode 211 and the solder element 213). In some arrangements, the thickness T2 is less than the thickness T1. In some arrangements, the thickness T1 is along a direction DR1 substantially perpendicular to the direction DR2, and the thickness T2 is along the direction DR2.

Referring to FIG. 1A, in some arrangements, the solder element 411 further includes an upper portion having a thickness T3 and over the terminal (e.g., the electrode 211 and the solder element 213). In some arrangements, the upper portion and the first lower portion are at opposite sides of the terminal (e.g., the electrode 211 and the solder element 213), and the thickness T3 is less than the thickness T1. In some arrangements, the solder element 411 further includes a second lower portion having a thickness T4 and between an upper surface of the protective element 30 and a lower surface of the terminal (e.g., the electrode 211 and the solder element 213). In some arrangements, the thickness T4 is less than the thickness T2. In some arrangements, the second lower portion of the solder element 411 having the thickness T4 contacts the upper surface of the protective element 30 and the lower surface of the terminal (e.g., the electrode 211 and the solder element 213). In some arrangements, the terminal (e.g., the electrode 211 and the solder element 213) is spaced apart from the upper surface of the protective element 30 by the second lower portion of the solder element 411. In some arrangements, the second lower portion of the solder element 411 having the thickness T4 vertically overlaps the protective element 30 and the pad 111, and the first lower portion of the solder element 411 having the thickness T1 is free from vertically overlapping the protective element 30.

Referring to FIG. 1A, in some arrangements, the solder element 412 includes a first lower portion having a thickness T1′ and between the terminal (e.g., the electrode 212 and the solder element 214) and the pad 112. In some arrangements, the solder element 412 further includes a lateral portion having a thickness T2′ and over a sidewall of the terminal (e.g., the electrode 212 and the solder element 214). In some arrangements, the thickness T2′ is less than the thickness T1′. In some arrangements, the thickness T1′ is along the direction DR1, and the thickness T2′ is along the direction DR2 substantially perpendicular to the direction DR1. In some arrangements, the thickness T1′ is different from the thickness T1.

Referring to FIG. 1A, in some arrangements, the solder element 412 further includes a second lower portion having a thickness T4′ and between an upper surface of the protective element 30 and a lower surface of the terminal (e.g., the electrode 212 and the solder element 214). In some arrangements, the thickness T4′ is less than the thickness T2′. In some arrangements, the second lower portion of the solder element 412 having the thickness T4′ contacts the upper surface of the protective element 30 and the lower surface of the terminal (e.g., the electrode 212 and the solder element 214). In some arrangements, the terminal (e.g., the electrode 212 and the solder element 214) is spaced apart from the upper surface of the protective element 30 by the second lower portion of the solder element 412. In some arrangements, the second lower portion of the solder element 412 having the thickness T4′ vertically overlaps the protective element 30 and the pad 112, and the first lower portion of the solder element 412 having the thickness T1′ is free from vertically overlapping the protective element 30. In some arrangements, the thickness T2′ is different from the thickness T2. In some arrangements, the thickness T4′ is different from the thickness T4.

Referring to FIG. 1B, in some arrangements, the solder element 421 contacts the pad 121 by a contact length 421L, the solder element 422 contacts the pad 122 by a contact length 422L, and the contact length 421L is substantially the same as the contact length 422L. In some arrangements, the solder element 421 connects or electrically connects the solder element 223 to the pad 121, and a bonding surface or a contact surface between the solder elements 421 and 223 includes an irregular surface. In some arrangements, the solder element 422 connects or electrically connects the solder element 224 to the pad 122, and a bonding surface or a contact surface between the solder elements 422 and 224 includes an irregular surface. In some arrangements, the solder element 421 includes a first lower portion having a thickness T1, a lateral portion having a thickness T2 less than the thickness T1, an upper portion having a thickness T3 less than the thickness T1, and a second lower portion having a thickness T4 less than the thickness T2. In some arrangements, the solder element 422 includes a first lower portion having a thickness T1′, a lateral portion having a thickness T2′ less than the thickness T1′, and a second lower portion having a thickness T4′ less than the thickness T2'.

Referring to FIG. 1C, in some arrangements, the solder element 431 contacts the pad 131 by a contact length 431L, the solder element 432 contacts the pad 132 by a contact length 432L, and the contact length 431L is substantially the same as the contact length 432L. In some arrangements, the solder element 431 connects or electrically connects the solder element 233 to the pad 131, and a bonding surface or a contact surface between the solder elements 431 and 233 includes an irregular surface. In some arrangements, the solder element 432 connects or electrically connects the solder element 234 to the pad 132, and a bonding surface or a contact surface between the solder elements 432 and 234 includes an irregular surface. In some arrangements, the solder element 431 includes a first lower portion having a thickness T1, a lateral portion having a thickness T2 less than the thickness T1, an upper portion having a thickness T3 less than the thickness T1, and a second lower portion having a thickness T4 less than the thickness T2. In some arrangements, the solder element 432 includes a first lower portion having a thickness T1′, a lateral portion having a thickness T2′ less than the thickness T1′, an upper portion having a thickness T3′ less than the thickness T1′, and a second lower portion having a thickness T4′ less than the thickness T2′.

In some arrangements, the thickness (e.g., the thickness T1a, T2a, and/or T3a) of the solder element 213 is greater than the thickness (e.g., the thickness T1, T2, and/or T3) of the solder element 411. In some arrangements, the thickness (e.g., the thickness T1a′, T2a′, and/or T3a′) of the solder element 214 is greater than the thickness (e.g., the thickness T1′ and/or T2′) of the solder element 412.

Referring to FIG. 1A, in some arrangements, the package structure 1 further includes an intermetallic compound (IMC) layer 215 between the solder element 213 and the solder element 411. In some arrangements, the IMC layer 215 includes an irregular surface of the bonding surface or the contact surface (e.g., the surface 213a) between the solder elements 213 and 411. In some arrangements, the package structure 1 further includes an IMC layer 216 between the solder element 214 and the solder element 412. In some arrangements, the IMC layer 216 includes an irregular surface of the bonding surface or the contact surface (e.g., the surface 214a) between the solder elements 214 and 412.

Referring to FIG. 1B, in some arrangements, the package structure 1 further includes an IMC layer 225 between the solder element 223 and the solder element 421. In some arrangements, the IMC layer 225 includes an irregular surface of the bonding surface or the contact surface between the solder elements 223 and 421. In some arrangements, the package structure 1 further includes an IMC layer 226 between the solder element 224 and the solder element 422. In some arrangements, the IMC layer 226 includes an irregular surface of the bonding surface or the contact surface between the solder elements 224 and 422.

Referring to FIG. 1C, in some arrangements, the package structure 1 further includes an IMC layer 235 between the solder element 233 and the solder element 431. In some arrangements, the IMC layer 235 includes an irregular surface of the bonding surface or the contact surface between the solder elements 233 and 431. In some arrangements, the package structure 1 further includes an IMC layer 236 between the solder element 234 and the solder element 432. In some arrangements, the IMC layer 236 includes an irregular surface of the bonding surface or the contact surface between the solder elements 234 and 432.

The encapsulant 50 may encapsulate the electronic components 21, 22, and 23. In some arrangements, the encapsulant 50 encapsulates the solder elements 411, 412, 421, 422, 431, and 432. In some arrangements, portions of the encapsulant 50 are filled in gaps between the solder elements 411, 412, 421, 422, 431, and 432. The encapsulant 50 may include an epoxy resin having fillers dispersed therein, a molding compound (e.g., an epoxy molding compound or other molding compound), polyimide (PI), a phenolic compound or material, a polymer material with silicone dispersed therein, or a combination thereof.

According to some arrangements of the present disclosure, the protective element 30 vertically overlaps the electronic component (e.g., the electronic components 21, 22, and 23) to define relatively small gaps between the bottom surface of the terminals of the electronic component and the top surface of the protective element 30. As a result, the small volume or space provided by the small gaps can reduce the chance (e.g., the volume) of the solder element (e.g., the solder elements 411, 412, 421, 422, 431, and 432) flowing upwards along the gaps to extend over the terminals of the electronic component. Therefore, formation of relatively large volumes of the solder elements over the terminals can be reduced, and thus short circuit between the terminals of the electronic component caused by the overflowing solder element connecting the terminals can be prevented.

In addition, according to some arrangements of the present disclosure, the pads (e.g., the pads 111 and 112) under the electronic component (e.g., the electronic component 21) are recessed with respect to lateral sides of the electronic component. Therefore, the distance between adjacent electronic components can be reduced, thus the number of electronic components per unit area of the package structure can be increased accordingly.

Moreover, according to some arrangements of the present disclosure, the distance between adjacent pads (e.g., the pads 111 and 112) under the electronic component (e.g., the electronic component 21) is relatively small because the pads are recessed with respect to lateral sides of the electronic component. As a result, the volume of the portion of the encapsulant 50 filled in the gap between the pads is reduced, the effect of mismatch of coefficient of thermal expansion (CTE) resulted from the encapsulant 50 contacting the pads and the substrate can be reduced accordingly. Therefore, the delamination risk due to the mismatch of CTEs of different materials can be lowered, and thus the reliability of the package structure 1 can be increased.

Furthermore, according to some arrangements of the present disclosure, the protective element 30 extends over the pads (e.g., the pads 111 and 112) under the electronic component (e.g., the electronic component 21) by different lengths. As a result, the different coverages over the pads by the protective element 30 can compensate the difference in the width of the pads. For example, the larger pad may be covered by the protective element 30 by a larger area, the smaller pad may be covered by the protective element 30 by a smaller area, and thus the exposed areas of the pads may have substantially equal areas for contacting solder elements. Therefore, the volumes or amounts of the solder elements on the pads may be substantially uniform, thus the contact areas between the solder elements and the pads can be relatively uniform, which can increase the reliability of the package structure while preventing the solder bridging issue.

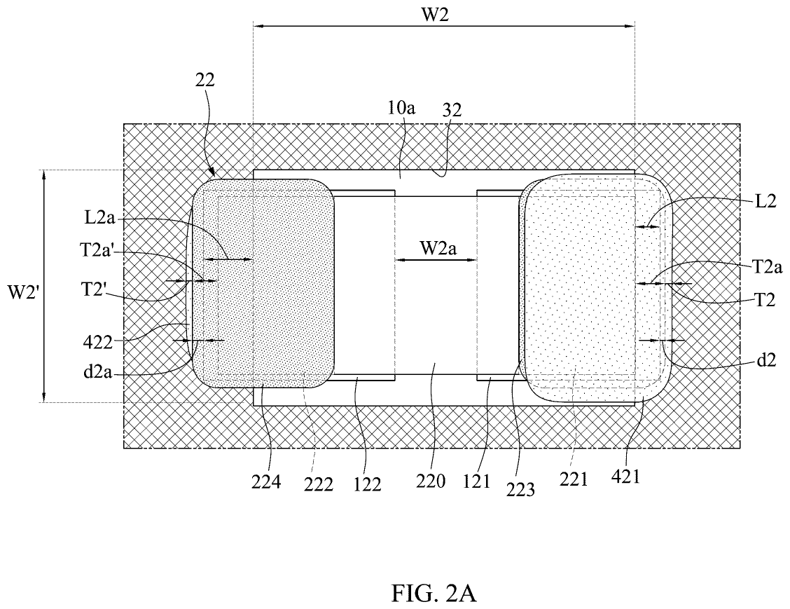

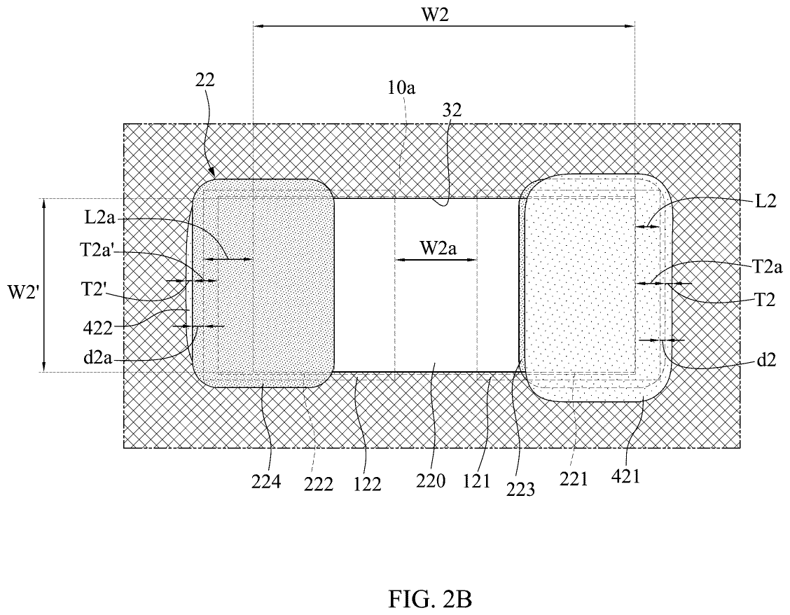

FIG. 2A is a top view of a portion of a package structure in accordance with some arrangements of the present disclosure. In some arrangements, FIG. 2A is a top view of a portion 1B of the package structure 1 illustrated in FIG. 1 and FIG. 1B.

In some arrangements, the opening 32 has a width W2 and a length W2′. In some arrangements, a projection of the electronic component 22 partially overlaps the opening 32 of the protective element 30 from a top view perspective.

FIG. 2B is a top view of a portion of a package structure in accordance with some arrangements of the present disclosure. In some arrangements, FIG. 2B is a top view of a portion 1B of the package structure 1 illustrated in FIG. 1 and FIG. 1B.

In some arrangements, a projection of the electronic component 22 entirely covers the opening 32 of the protective element 30 from a top view perspective.

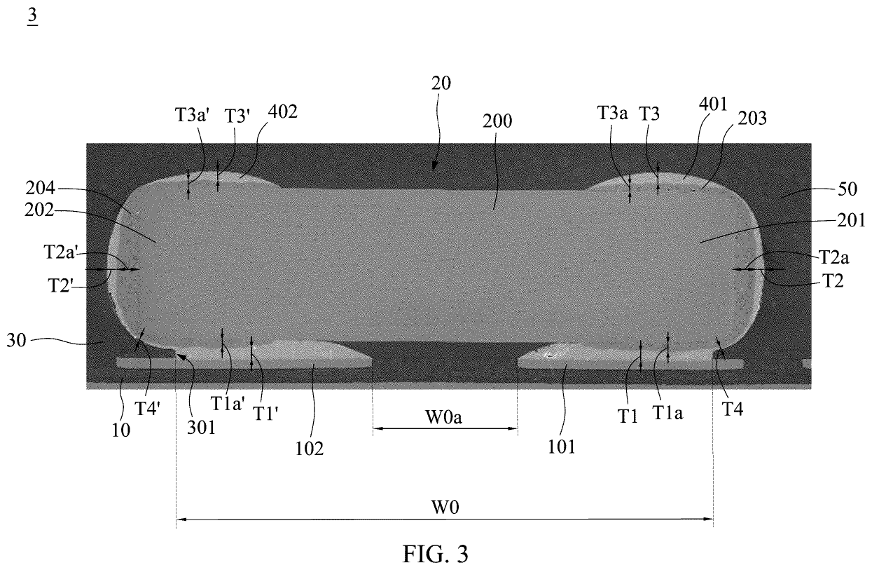

FIG. 3 is a cross-section of a package structure 3 in accordance with some arrangements of the present disclosure. The package structure 3 is similar to the package structure 1 in FIG. 1, and the differences therebetween are described as follows.

In some arrangements, the package structure 3 includes a substrate 10, an electronic component 20, a protective element 30, solder elements 401 and 402, and an encapsulant 50.

In some arrangements, the substrate 10 includes pads 101 and 102. The pads 101 and 102 are the same as or similar to the pads 111 and 112, and the description thereof are omitted hereinafter.

In some arrangements, the electronic component 20 is connected to the pads 101 and 102. In some arrangements, the electronic component 20 is disposed over the electrically connected to the pads 101 and 102. In some arrangements, the pads 101 and 102 are spaced apart from each other by a distance W0a. In some arrangements, the electronic component 20 includes a base layer 200 and electrodes 201 and 202 (also referred to as “contacts”). The electrode 201 may be opposite to the electrode 202. The base layer 200 may be an insulating layer, e.g., a ceramic layer. In some arrangements, the electronic component 20 further includes a solder element 203 covering the electrode 201 and a solder element 204 covering the electrode 202. The electrode 201 and the solder element 203 may be referred to as a terminal (also referred to as “a first terminal”) of the electronic component 20, and the electrode 202 and the solder element 204 (also referred to as “a second terminal”) may be referred to as a terminal of the electronic component 20. In some arrangements, the terminals of the electronic component 20 are electrically connected to the pads 101 and 102, respectively.

In some arrangements, the solder element 203 includes a lower portion having a thickness T1a, a lateral portion having a thickness T2a, and an upper portion having a thickness T3a. In some arrangements, the solder element 204 includes a lower portion having a thickness T1a′, a lateral portion having a thickness T2a′, and an upper portion having a thickness T3a′. In some arrangements, the thickness T1a is different from the thickness T1a′. In some arrangements, the thickness T2a is different from the thickness T2a′. In some arrangements, the thickness T3a is different from the thickness T3a′.

In some arrangements, the protective element 30 defines an opening 301 to partially expose the pads 101 and 102. In some arrangements, a width W0 of the opening 301 is less than a width 20W of the electronic component 20. In some arrangements, the protective element 30 extends over the pad 101 and over the pad 102 by different lengths.

In some arrangements, the solder elements 401 and 402 may be disposed between the substrate 10 and the electronic component 20. The solder elements 401 and 402 may be referred to as solder structures, solder layers, solder balls, or the like. In some arrangements, the solder elements 401 and 402 and the solder elements 203 and 204 include different materials.

In some arrangements, the solder element 401 connects or electrically connects the solder element 203 to the pad 101, and a bonding surface or a contact surface between the solder elements 401 and 203 includes an irregular surface. In some arrangements, the solder element 402 connects or electrically connects the solder element 204 to the pad 102, and a bonding surface or a contact surface between the solder elements 422 and 224 includes an irregular surface. In some arrangements, the solder element 401 includes a first lower portion having a thickness T1, a lateral portion having a thickness T2 less than the thickness T1, an upper portion having a thickness T3 less than the thickness T1, and a second lower portion having a thickness T4 less than the thickness T2. In some arrangements, the solder element 402 includes a first lower portion having a thickness T1′, a lateral portion having a thickness T2′ less than the thickness T1′, an upper portion having a thickness T3′ less than the thickness T1′, and a second lower portion having a thickness T4′ less than the thickness T2′.

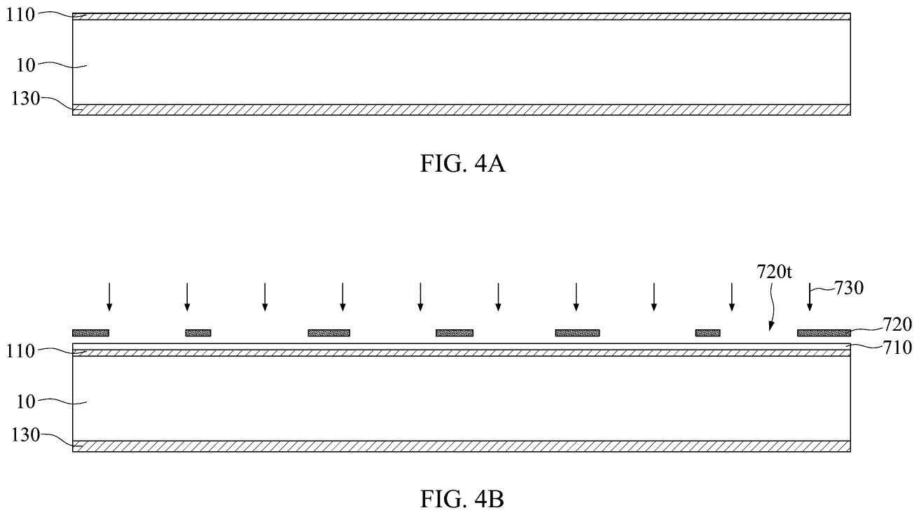

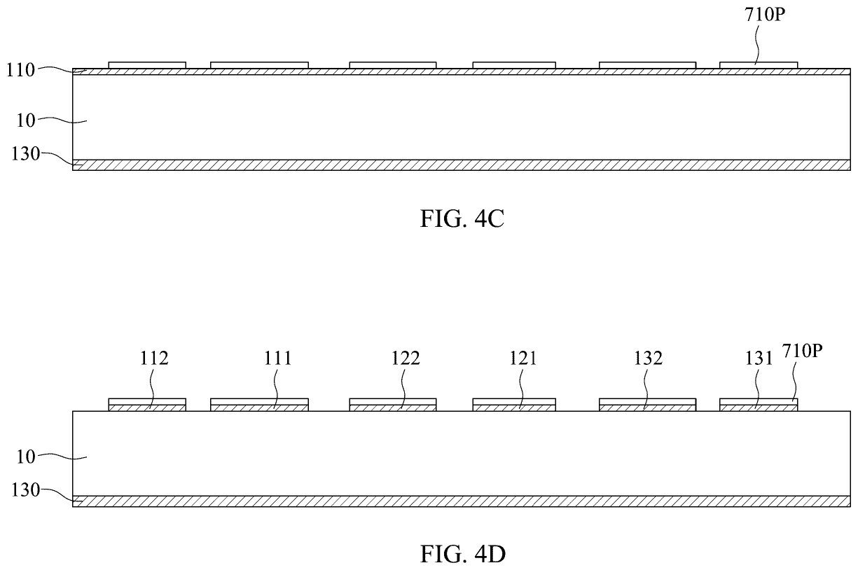

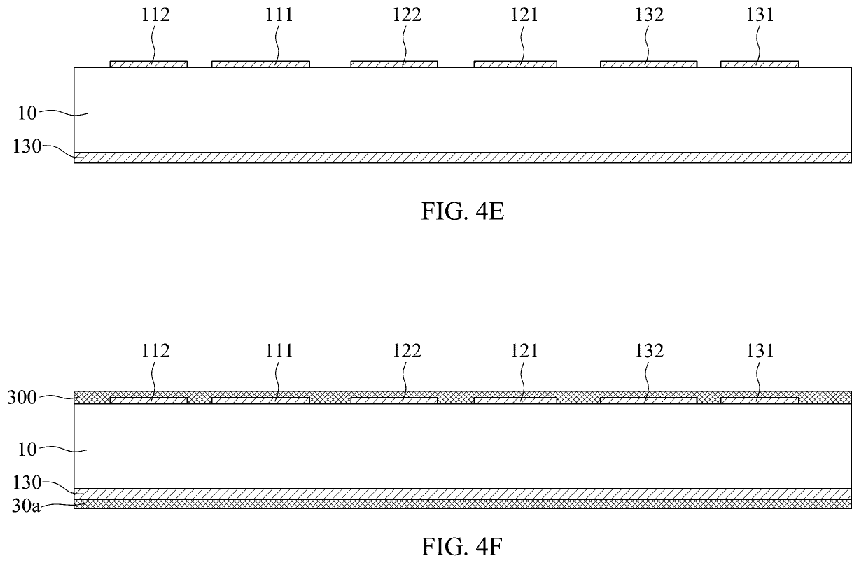

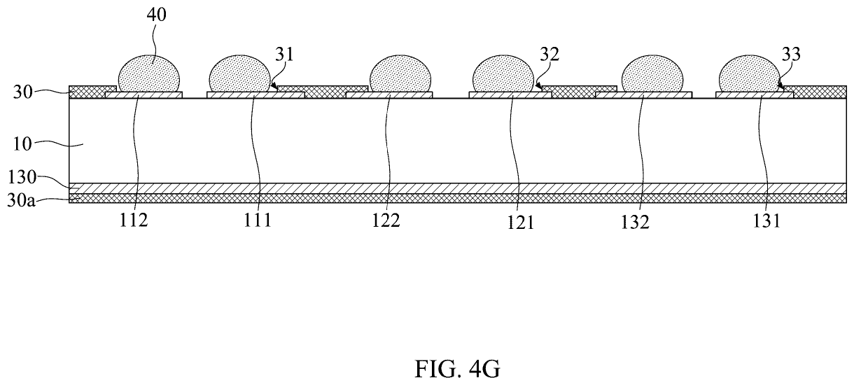

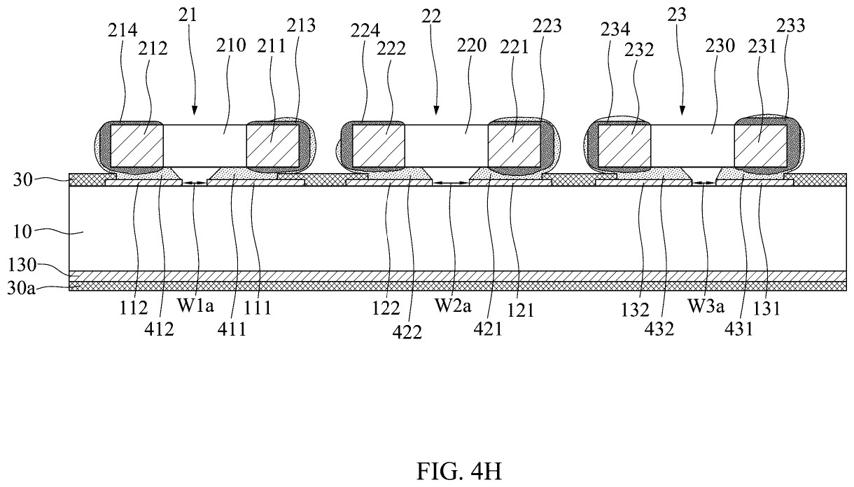

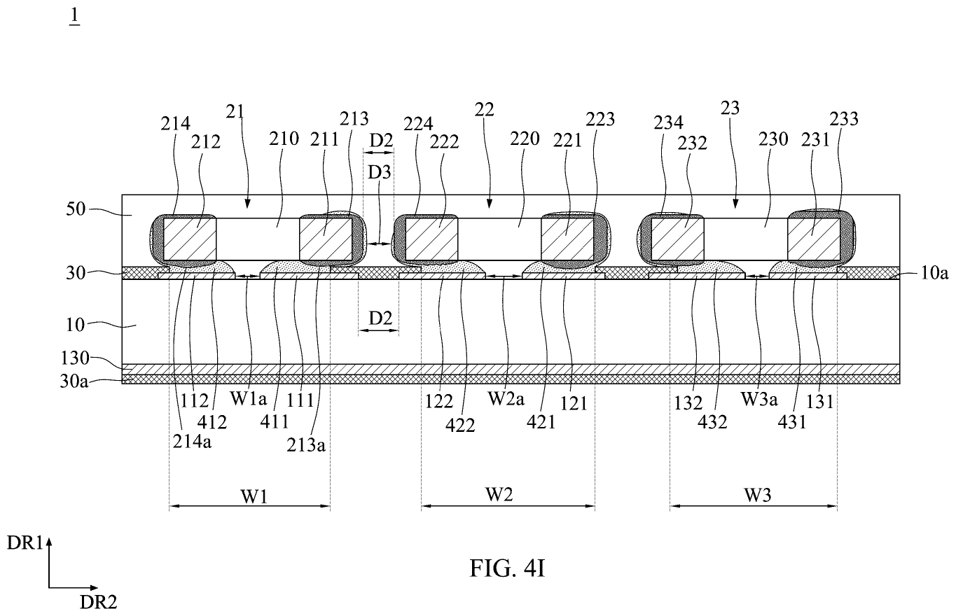

FIG. 4A to FIG. 4I illustrate various stages of an exemplary method of forming a package structure in accordance with some arrangements of the present disclosure.

Referring to FIG. 4A, a substrate 10 may be provided, and conductive layers 110 and 130 may be disposed or formed on opposite surfaces of the substrate 10. The conductive layers 110 and 130 may be formed by deposition, plating, lamination, or a combination thereof. In some arrangements, each of the conductive layers 110 and 130 includes a Cu foil and a Cu plating layer over the Cu foil.

Referring to FIG. 4B, a photoresist layer 710 may be disposed on the conductive layer 110, a mask layer 720 defining openings 720t may be disposed over the photoresist layer 710, and an exposure operation may be performed on the photoresist layer 710 by irradiating a light 730 through the openings 720t of the mask layer 720 over the photoresist layer 710.

Referring to FIG. 4C, the photoresist layer 710 may be developed to form photoresist patterns 710P.

Referring to FIG. 4D, the conductive layer 110 may be etched according to the photoresist patterns 710P to form pads 111, 112, 121, 122, 131, and 132.

Referring to FIG. 4E, the photoresist patterns 710P may be removed.

Referring to FIG. 4F, a protective layer 300 may be disposed or formed over the pads 111, 112, 121, 122, 131, and 132, and a protective layer 30a may be disposed or formed on the conductive layer 130. The protective layers 300 and 30a may be formed by printing.

Referring to FIG. 4G, portions of the protective layer 300 may be removed to form a protective element 30 having openings 31, 32, and 33, and solder materials 40 may be disposed over the 111, 112, 121, 122, 131, and 132 in the openings 31, 32, and 33.

Referring to FIG. 4H, a reflow operation may be performed on the solder materials 40 to form solder elements 411, 412, 421, 422, 431, and 432 to bond electronic components 21, 22, and 23 to the pads 111, 112, 121, 122, 131, and 132.

Referring to FIG. 4I, an encapsulant 50 may be disposed to encapsulate the electronic components 21, 22, and 23. As such, the package structure 1 illustrated in FIG. 1 may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate comprising a first pad and a second pad;
an electronic component connected to the first pad and the second pad; and
a protective element at least partially between the substrate and the electronic component, wherein the protective element extends over the first pad by a first length and over the second pad by a second length different from the first length.

2. The package structure as claimed in claim 1, wherein a length of the first pad is different from a length of the second pad.

3. The package structure as claimed in claim 2, wherein the length of the first pad is greater than the length of the second pad, and the first length of the protective element is greater than the second length of the protective element.

4. The package structure as claimed in claim 1, further comprising a first solder element contacting the first pad by a first contact length and a second solder element contacting the second pad by a second contact length substantially the same as the first contact length.

5. The package structure as claimed in claim 1, wherein the first pad is recessed with respect to a first side of the electronic component, and the second pad is recessed with respect to a second side opposite to the first side of the electronic component.

6. The package structure as claimed in claim 5, wherein the first pad is recessed with respect to the first side of the electronic component by a first distance, and the second pad is recessed with respect to the second side of the electronic component by a second distance different from the first distance.

7. The package structure as claimed in claim 1, wherein the protective element defines an opening to partially expose the first pad and the second pad, and a width of the opening is less than a width of the electronic component.

8. The package structure as claimed in claim 7, wherein a projection of the electronic component entirely covers the opening of the protective element from a top view perspective.

9. A package structure, comprising:
a substrate comprising a first pad;
an electronic component disposed over the first pad and comprising a first terminal; and
a first solder element connecting the first terminal to the first pad,
wherein the first solder element comprises a first lower portion between the first terminal and the first pad and having a first thickness, and the first solder element further comprises a lateral portion over a sidewall of the first terminal and having a second thickness less than the first thickness.

10. The package structure as claimed in claim 9, wherein the first solder element further comprises an upper portion having a third thickness less than the first thickness, the upper portion and the first lower portion being at opposite sides of the first terminal.

11. The package structure as claimed in claim 9, further comprising a protective element over the substrate and defining an opening to partially expose the first pad, wherein the first solder element further comprises a second lower portion between an upper surface of the protective element and a lower surface of the first terminal and having a third thickness less than the second thickness.

12. The package structure as claimed in claim 11, wherein the second lower portion of first the solder element contacts the upper surface of the protective element and the lower surface of the first terminal.

13. The package structure as claimed in claim 11, wherein the first terminal is spaced apart from the upper surface of the protective element by the second lower portion of the first solder element.

14. The package structure as claimed in claim 11, wherein the second lower portion of the first solder element vertically overlaps the protective element and the first pad, and the first lower portion of the first solder element is free from vertically overlapping the protective element.

15. A package structure, comprising:
a substrate comprising a first pad exposed from an upper surface of the substrate;
a first electronic component comprising a first electrode and a first solder element covering the first electrode; and
a first solder structure connecting the first solder element to the first pad, wherein a contact surface between the first solder element and the first solder structure comprises an irregular surface.

16. The package structure as claimed in claim 15, further comprising a first intermetallic compound (IMC) layer between the first solder element and the first solder structure, wherein the first IMC layer comprises the contact surface.

17. The package structure as claimed in claim 15, wherein the first electronic component further comprises a second electrode and a second solder element covering the second electrode, and a thickness of the first solder element is different from a thickness of the second solder element.

18. The package structure as claimed in claim 17, wherein the substrate further comprises a second pad, the package structure further comprises a second solder structure connecting the second solder element to the second pad, and a thickness of the first solder structure is different from a thickness of the second solder structure.

19. The package structure as claimed in claim 15, further comprising a protective element over the substrate and defining an opening to partially expose the first pad, wherein the first solder element partially overlaps the protective element is a direction substantially parallel to the upper surface of the substrate.

20. The package structure as claimed in claim 15, wherein the first electrode is electrically connected to and spaced apart from the first solder structure by the first solder element.
